(19) United States
(12) Patent Application Publication
(10) Pub. No.: US 2006/0017059 A1
(43) Pub. Date: Jan. 26, 2006

(54) Packaged OLED light source

(75) Inventors: David R. Strip, Albuquerque, NM (US); Gustavo R. Paz-Pujalt, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/896,123

(22) Filed: Jul. 21, 2004

(51) Int. Cl. H01L 33/00

(52) U.S. Cl. 257/99; 257/100

(57) ABSTRACT

A packaged organic light emitting diode (OLED) light source, comprising one or more OLED devices fabricated on a substrate and sealed with a cover, wherein at least one of the substrate and cover comprises a polymer layer and the OLED device is packaged in a sealed storage container having a permeability to water and oxygen that is lower than that of the polymer layer.

### FIELD OF THE INVENTION

The present invention relates to organic light emitting diode (OLED) light sources, and more particularly to packaged OLED light sources suitable for disposable applications in which light is required for only short periods of time.

### BACKGROUND OF THE INVENTION

Light is often used for marking, signaling and warning in routine and emergency applications. A number of methods exist to generate light for these purposes including combustion, chemiluminescence, and electroluminescence. Flares are a common example of combustion-based light sources. This general class of materials represents a fire hazard in storage, transport, and use. They may be difficult to use in wet environments. Chemilumiscence is based on combining chemicals that react to emit light. Glowsticks are a familiar example of chemiluminescent products. While safe in transport and use, the level of light produced by chemiluminscence is generally not very intense. Furthermore, the devices are frequently bulky and have relatively short lives. Inorganic LEDs are examples of electroluminscent devices. LEDs are capable of high brightness and are efficient in conversion of electricity to light. However, LEDs are point sources of light and therefore require considerable effort to be used as a large area diffuse source. Organic LEDs (OLEDs) provide adequate brightness over a large area, but are either made with glass substrate and encapsulating cover layers and are therefore heavy and fragile, or else they are produced with a polymer film substrate and/or polymer barrier cover layer. For example, in U.S. Pat. No. 5,884,363 Gu et. al., disclose a small molecule OLED device deposited on a polyester substrate. While use of such polymeric films reduces the weight and fragility of the devices, it is well-known in the field that the permeability of polyester films to oxygen and water is typically much higher than that of glass, and that OLEDs fabricated on or covered by polymeric films will accordingly have a relatively short effective life as measured from the time of manufacture.

There is a need therefore for an improved lighting source suitable for signaling, marking, and warning that is lightweight, safe, can be produced in an area-covering form, and can be stored for extended periods until a desired time of use.

### SUMMARY OF THE INVENTION

The need is met according to the present invention by providing a packaged organic light emitting diode (OLED) light source, comprising one or more OLED devices fabricated on a substrate and sealed with a cover, wherein at least one of the substrate and cover comprises a polymer layer and the OLED device is packaged in a sealed storage container having a permeability to water and oxygen that is lower than that of the polymer layer.

### Advantages

The OLED light source is advantageous because it does not involve flammable materials, can be stored for long-periods of time, is lightweight and occupies a small volume. In addition, by selecting the appropriate form factor, the OLED can easily be produced as a broad-area diffuse light source.

### BRIEF DESCRIPTION OF THE DRAWINGS

FIG. 1 is a perspective view of one embodiment of the invention.

FIG. 2 is a diagram showing a longitudinal cross section of the OLED component of one embodiment of the invention.

FIG. 3 is a view of a folded OLED component of one embodiment of the invention.

FIGS. 4a-4c are views of alternative patternings of the OLED components of various embodiments of the invention.

FIGS. 5a-5b are views of embodiments of the OLED component of the invention in the form of safety vests and belts.

FIGS. 6a-6b are views of two embodiments of the OLED component of the invention as batons.

FIGS. 7a-7b are views of an embodiment of the OLED component of the invention in the form of a fiber.

FIG. 8 is a schematic view of a basic OLED device.

### DETAILED DESCRIPTION OF THE INVENTION

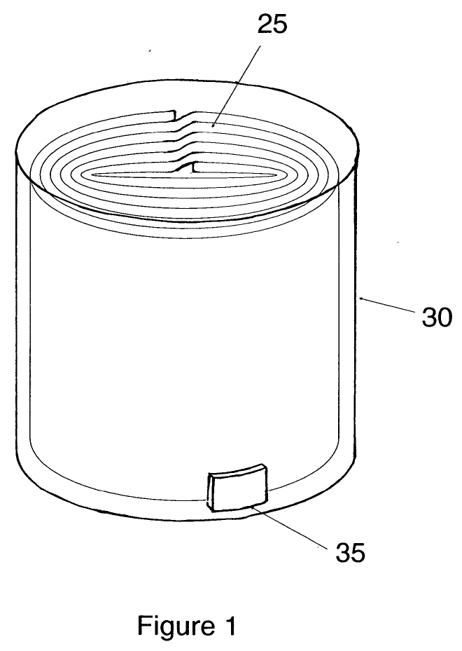

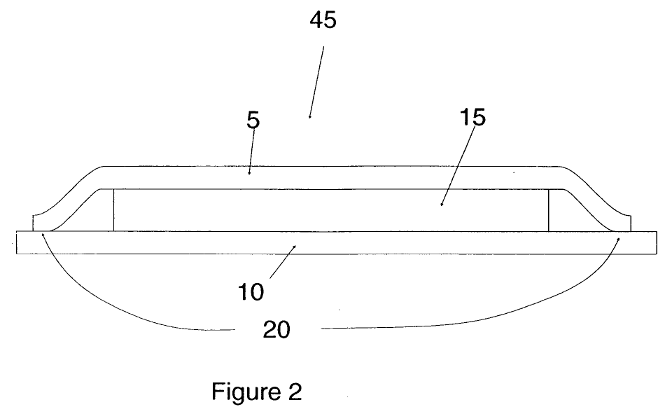

Referring to FIG. 1, a roll 25 of OLED devices is packaged inside a sealed outer package 30 along with a desiccant 35. FIG. 2 shows the basic composition of the OLED device 45. The device consists of a substrate 10 on which an OLED layer stack 15 is deposited. The OLED layer stack 15 is then sealed 20 between the substrate 10 and the cover 5. At least one of the substrate and cover must be optically transmissive for the light to be visible. The transmissive layer may be a polymer film such as PET or PEN, among many possible materials. In a preferred embodiment, both the substrate and the cover may be made of polymer films. OLED devices are well-known to be susceptible to degradation through reactions with oxygen and water vapor. It is further known that polymers such as PET and PEN do not provide adequate barriers to water and oxygen to prevent degradation of OLED devices for extended periods. By packaging the roll 25 of OLED devices in an airtight sealed storage container 30, where the storage container has a permeability to water and oxygen that is lower than that of the polymer layer of the substrate or cover, we reduce the availability of oxygen and water to degrade the OLED material. This reduces the need to utilize extremely low-permeability materials for the substrate 10 and cover 5. In specific embodiments, the storage container may be comprised of materials having a permeability to water of less than 10⁻⁵ g H₂O/m²/day, preferably less than 10⁻⁶ g H₂O/m²/day, more preferably less than 10⁻⁷ g H₂O/m²/day and even more preferably less than 10⁻⁸ g H₂O/m²/day. Examples of materials which may be used for the storage container include glass and metals, as well as metal layer coated polymer films. Addition of a desiccant 35 further reduces the availability of free water vapor for reaction with the OLED device. In a similar manner, an oxygen getter could be added to the package to scavenge oxygen. Additionally, or alternatively, the package could be filled with a dry, inert gas before sealing.

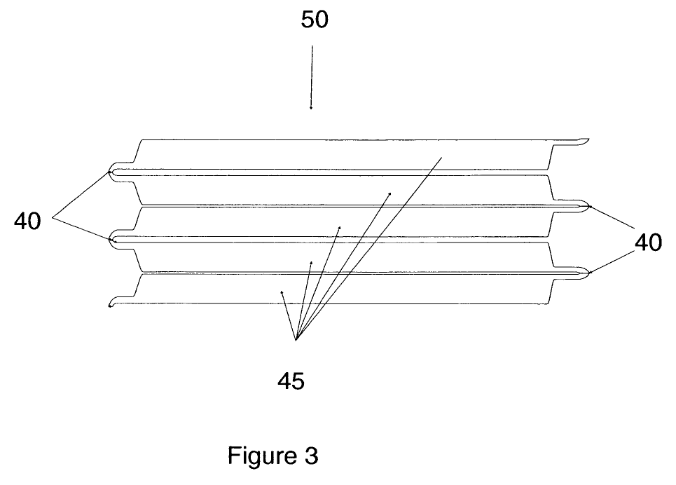

The OLED devices to be packaged in a storage container may take many forms. The use of polymer films for substrates and/or cover layers provides enhanced flexibility of the OLED light sources. FIG. 1, e.g., shows a roll 25 of OLED devices. FIG. 3 shows an alternative arrangement in which the OLED device 45 is arranged in a fan-fold configuration 50. By providing a seal at the folds 40, propagation of materials promoting degradation can be delayed from one panel to another. Although the storage container 30 in FIG. 1 shows a rigid can, the container could easily be a flexible metal foil pouch, a metallized plastic container, or a glass container. In addition to the roll and fan-fold forms shown here, sheets of predetermined sizes, packaged individually or in stacks in an airtight storage container are anticipated.

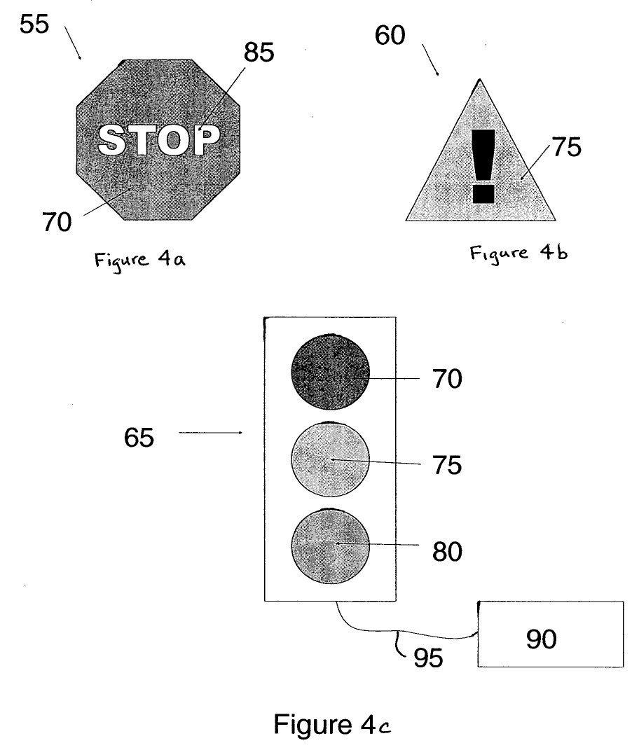

It is well-known to be able to produce OLED materials emitting a broad range of colors. Further, it is well-known to deposit the OLED device materials in specific patterns. Referring to FIGS. 4a-4c, lightweight, short-life OLED devices are shown in a variety of patterns—a stop sign 55, a caution sign 60, and a traffic signal 65. By utilizing colored emitters such as red 70 and white 85, the stop sign 55 maintains its familiar appearance, yet is visible at large distances at night when it might be otherwise invisible. This is particularly important in emergency uses. Similarly, a caution sign 60 utilizes a yellow emitter 75. The traffic light 65, with red 70, yellow 75, and green 80 emitters, can be especially important for maintaining safety and traffic control in situations where a traffic signal cannot be installed. Control electronics 90 can be connected to the signal 65 via a wire 95 to provide full traffic signal functionality. The potential lightweight nature of the light sources employed in the invention (due to the use of polymer layers for at least one of, and preferably both the substrate and cover) allows these devices to be applied to a variety of temporary surfaces. For example, the cover 5 or the substrate 10 may be coated with an adhesive for mounting to any reasonably smooth surface. The cover 5 or substrate 10 may be made of a magnetic material allowing the device to be affixed to any iron or steel surface. The device 45 may contain holes for hanging from hooks, strings, etc., outside the seal boundary, or within the seal boundary with additional seals at the penetration.

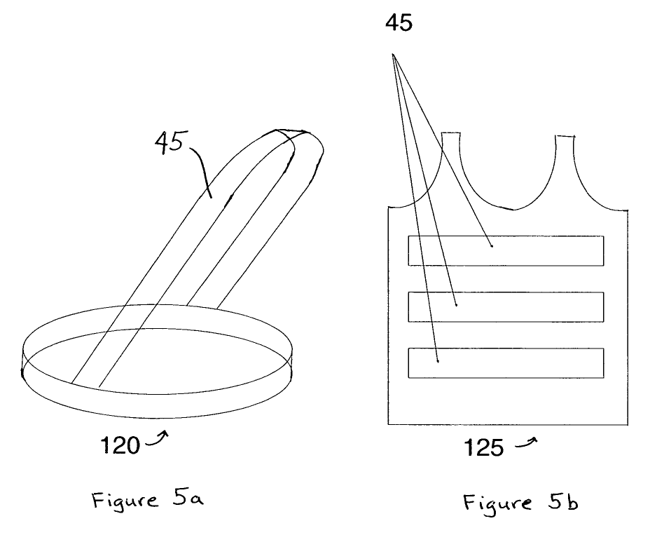

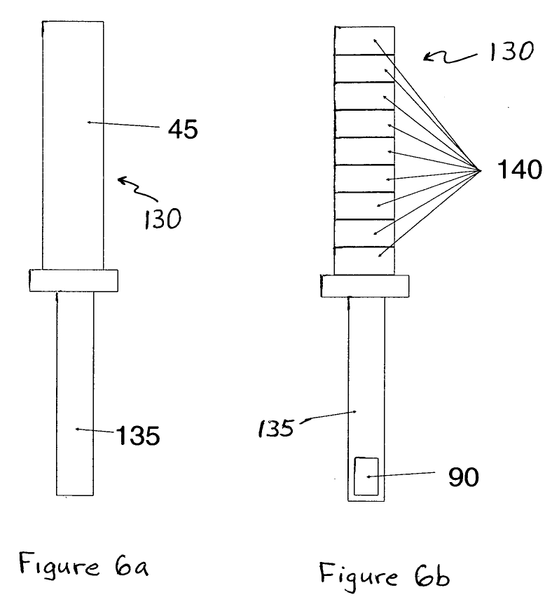

Lightweight, flexible OLED devices can be incorporated into apparel for safety, entertainment, or other reasons. FIGS. 5a-5b show a Sam Browne belt 120 and a vest 125. The Sam Browne belt is made essentially entirely of flexible OLED material, while the vest incorporates replaceable strips of OLED material. FIG. 6a shows a handheld baton 130 consisting of a handle 135 and a replaceable lightweight OLED device 45. The handle would typically contain batteries and a switch. The OLED device 45 may be subdivided into multiple independently addressable OLED deyices 140 as shown in FIG. 6b. Control electronics 90 can be utilized to cause the addressable OLED devices 140 to be lit in a plurality of pre-determined sequences, or a random sequence. In addition, the addressable OLED devices 140 may be a plurality of different colors to increase the impact of the device.

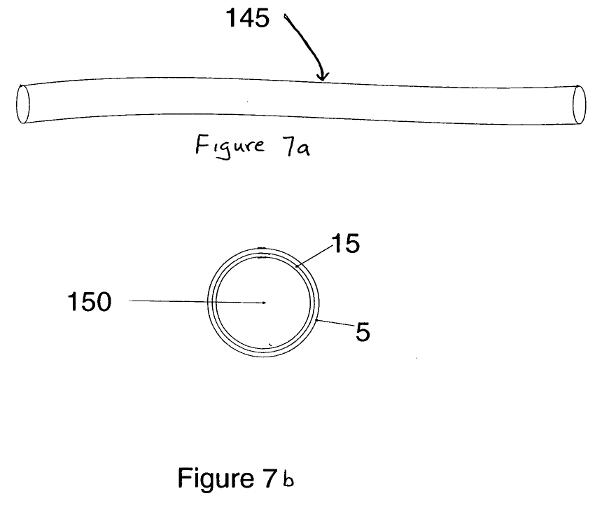

FIGS. 7a-7b show another embodiment of a OLED similar to a rope 145. Cross-sectional FIG. 7b illustrates the rope core 150 is coated with an OLED stack 15 and provided with a cover 5. The configuration of the OLED stack is such that the light is directed outwards. This contrasts with U.S. 20030099858A1 in which the core 150 is defined to be a fiber optic and the OLED stack 15 is oriented such that the light is directed inwards and coupled into the fiber optic. Individual strands of this material could be combined to form novelty devices such as necklaces, bracelets, or even wigs.

In a preferred embodiment, the invention is employed in a device that includes Organic Light Emitting Diodes (OLEDs) which are composed of small molecule or polymeric OLED materials as disclosed in but not limited to Tang et al. U.S. Pat. No. 4,769,292 and VanSlyke et al. U.S. Pat. No. 5,061,569. Many combinations and variations of organic light emitting materials can be used to fabricate such a device.

General Device Architecture

The present invention can be employed with most OLED device configurations. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

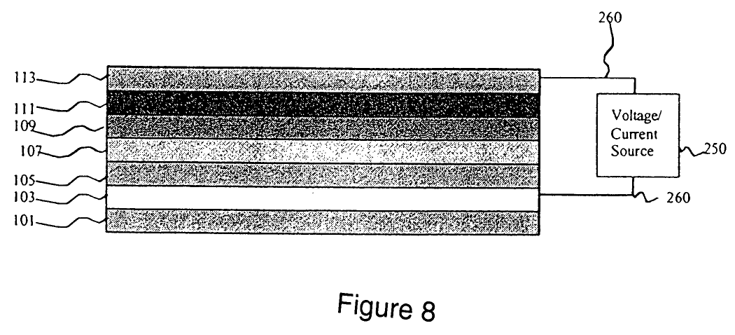

There are numerous configurations of the organic layers wherein the present invention can be successfully practiced. A typical structure is shown in FIG. 8 and is comprised of a substrate 101, an anode 103, a hole-injecting layer 105, a hole-transporting layer 107, a light-emitting layer 109, an electron-transporting layer 111, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. The total combined thickness of the organic layers is preferably less than 500 nm.

The anode and cathode of the OLED are connected to a voltage/current source 250 through electrical conductors 260. The OLED is operated by applying a potential between the anode and cathode such that the anode is at a more positive potential than the cathode. Holes are injected into the organic EL element from the anode and electrons are injected into the organic EL element at the cathode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate where either the cathode or anode can be in contact with the substrate. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, silicon, ceramics, and circuit board materials. Of course, in such case it is necessary to provide a light-transparent top electrode.

Anode

When EL emission is viewed through anode 103, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode electrode, the transmissive characteristics of anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful to provide a hole-injecting layer 105 between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino] triphenylamine). Alternative hole-injecting materials reportedly useful in organic EL devices are described in EP 0 891 121 A1 and EP 1 029 909 A1.

Hole-Transporting Layer (HTL)

The hole-transporting layer 107 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:
1,1-Bis(4-di-p-tolylaminophenyl)cyclohexane
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl
4,4′-Bis[N-(1-naphthyl)-N-(2-naphthyl)amino]biphenyl
4,4″-Bis[N-(1-naphthyl)-N-phenylamino]ₚ-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, the light-emitting layer (LEL) 109 of the organic EL element includes a luminescent or fluorescent material where electroluminescence is produced as a result of electron-hole pair recombination in this region. The light-emitting layer can be comprised of a single material, but more commonly consists of a host material doped with a guest compound or compounds where light emission comes primarily from the dopant and can be of any color. The host materials in the light-emitting layer can be an electron-transporting material, as defined below, a hole-transporting material, as defined above, or another material or combination of materials that support hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. Polymeric materials such as polyfluorenes and polyvinylarylenes (e.g., poly(p-phenylenevinylene), PPV) can also be used as the host material. In this case, small molecule dopants can be molecularly dispersed into the polymeric host, or the dopant could be added by copolymerizing a minor constituent into the host polymer.

An important relationship for choosing a dye as a dopant is a comparison of the bandgap potential which is defined as the energy difference between the highest occupied molecular orbital and the lowest unoccupied molecular orbital of the molecule. For efficient energy transfer from the host to the dopant molecule, a necessary condition is that the band gap of the dopant is smaller than that of the host material. For phosphorescent emitters it is also important that the host triplet energy level of the host be high enough to enable energy transfer from host to dopant.

Host and emitting molecules known to be of use include, but are not limited to, those disclosed in U.S. Pat. Nos. 4,768,292; 5,141,671; 5,150,006; 5,151,629; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline (oxine) and similar derivatives constitute one class of useful host compounds capable of supporting electroluminescence. Illustrative of useful chelated oxinoid compounds are the following:
CO-1: Aluminum trisoxine [alias, tris(8-quinolinolato)aluminum(III)]
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

Other classes of useful host materials include, but are not limited to: derivatives of anthracene, such as 9,10-di-(2-naphthyl)anthracene and derivatives thereof as described in U.S. Pat. No. 5,935,721, distyrylarylene derivatives as described in U.S. Pat. No. 5,121,029, and benzazole derivatives, for example, 2, 2′, 2″-(1,3,5-phenylene)tris[1-phenyl-1H-benzimidazole]. Carbazole derivatives are particularly useful hosts for phosphorescent emitters.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds.

Electron-Transporting Layer (ETL)

Preferred thin film-forming materials for use in forming the electron-transporting layer 111 of the organic EL elements of this invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Cathode

When light emission is viewed solely through the anode, the cathode 113 used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin electron-injection layer (EIL) in contact with the organic layer (e.g., ETL) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of A1 as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,393. Cathode materials are typically deposited by evaporation, sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

Other Common Organic Layers and Device Architecture

In some instances, layers 109 and 111 can optionally be collapsed into a single layer that serves the function of supporting both light emission and electron transportation. It also known in the art that emitting dopants may be added to the hole-transporting layer, which may serve as a host. Multiple dopants may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, U.S. 20020025419, EP 1 182 244, U.S. Pat. No. 5,683,823, U.S. Pat. No. 5,503,910, U.S. Pat. No. 5,405,709, and U.S. Pat. No. 5,283,182.

Additional layers such as electron or hole-blocking layers as taught in the art may be employed in devices of this invention. Hole-blocking layers are commonly used to improve efficiency of phosphorescent emitter devices, for example, as in U.S. 20020015859.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551, 5,851,709 and 6,066,357) and inkjet method (U.S. Pat. No. 6,066,357).

Encapsulation

As discussed above, most OLED devices are sensitive to moisture or oxygen, or both, so they are commonly sealed with an encapsulating cover in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation. While the present invention is specifically directed towards packaging of OLED light sources which have a degree of susceptibility to moisture and/or oxygen due to the use of at least one of a polymeric substrate or cover in place of a glass substrate and cover, the use of such prior art device encapsulation techniques may still be employed if desired in combination with a sealed storage container in accordance with the invention, to further enhance storage lifetime and device performance.

Optical Optimization

OLED devices can employ various well-known optical effects in order to enhance properties if desired. This includes optimizing layer thicknesses to yield maximum light transmission, providing dielectric mirror structures, replacing reflective electrodes with light-absorbing electrodes, providing anti-glare or anti-reflection coatings over the display, providing a polarizing medium over the display, or providing colored, neutral density, or color conversion filters over the display. Filters, polarizers, and anti-glare or anti-reflection coatings may be specifically provided over the cover or an electrode protection layer beneath the cover.

The invention has been described in detail with particular reference to certain preferred embodiments thereof, but it will be understood that variations and modifications can be effected within the spirit and scope of the invention.

### PARTS LIST

5 Cover layer
10 Substrate
15 OLED stack
20 Seal
25 Roll of OLED on flexible substrate
30 Outer package
35 Desiccant
40 Fold
45 OLED device
50 Fanfold OLED devices
55 Stop sign
60 Caution sign
65 Traffic light
70 Red emitter
75 Yellow emitter
80 Green emitter
85 White emitter
90 Control electronics
95 Wire
101 substrate
103 anode layer
105 hole-injecting layer
107 hole-transporting layer
109 light-emitting layer
111 electron-transporting layer
113 cathode layer
120 “Sam Browne” belt
125 Vest
130 Baton
135 Handle
140 Addressable OLED device
145 OLED “rope”
150 Core
250 voltage/current source
260 conductive wiring

What is claimed is:

1. A packaged organic light emitting diode (OLED) light source, comprising one or more OLED devices fabricated on a substrate and sealed with a cover, wherein at least one of the substrate and cover comprises a polymer layer and the OLED device is packaged in a sealed storage container having a permeability to water and oxygen that is lower than that of the polymer layer.

2. The packaged light source of claim 1 where the storage container comprises a rigid metal container.

3. The packaged light source of claim 1 where the storage container comprises a flexible metal foil container.

4. The packaged light source of claim 1 where the storage container comprises a flexible metal coated polymeric container.

5. The packaged light source of claim 1 where the storage container comprises a glass container.

6. The packaged light source of claim 5 where the glass container has a metal lid.

7. The packaged light source of claim 1 where the storage container is filled with a dry, inert gas prior to sealing.

8. The packaged light source of claim 1 where a desiccant is enclosed in the storage container along with the OLED device.

9. The packaged light source of claim 1 where an oxygen getter is enclosed in the storage container along with the OLED device.

10. The packaged light source of claim 1 where the storage container is reclosable.

11. The packaged light source of claim 1 where OLED device is packaged in a roll form.

12. The packaged light source of claim 1 where the OLED device is folded.

13. The packaged light source of claim 1 where a plurality of OLED devices in sheet form are packaged in a single storage container.

14. The packaged light source of claim 1 where the OLED device is in the form of a traffic sign.

15. The packaged light source of claim 1 where the OLED device is in the form of a traffic signal.

16. The packaged light source of claim 15 where the OLED device is attached to a control device to enable it to function as a traffic signal.

17. The packaged light source of claim 1 where the OLED device is in the form of a garment.

18. The packaged light source of claim 1 where the OLED device has a predetermined shape for attachment to a garment.

19. The packaged light source of claim 1 where the OLED device has a cylindrical shape.

20. The packaged light source of claim 19 where the OLED device has a plurality of independently lightable portions.

21. The packaged light source of claim 20 where the lightable portions are the same color.

22. The packaged light source of claim 20 where the lightable portions comprise a plurality of colors.

23. The packaged light source of claim 19 where the OLED device is mounted on a support which provides electrical power to the OLED device.

24. The packaged light source of claim 20 where the OLED device is mounted on a support where the support contains control electronics which light individually addressable portions of the OLED in a predetermined sequence.

25. The packaged light source of claim 1 where the OLED device is in the form of a fiber.

26. The packaged light source of claim 25 where the fiber is woven into the form of a fabric.

27. The packaged light source of claim 26 where the fabric is formed into a garment.

28. The packaged light source of claim 25 where a plurality of fibers are joined to form a wig.

29. The packaged light source of claim 25 where a plurality of fibers are joined to form a bundle.

30. The packaged light source of claim 1 where the storage container has a permeability to water of less than 10⁻⁵ g H₂O/m²/day.

31. The packaged light source of claim 1 where the storage container has a permeability to water of less than 10⁻⁶ g H₂O/m²/day.

32. The packaged light source of claim 1 where the storage container has a permeability to water of less than 10⁻⁷ g H₂O/m²/day.

33. The packaged light source of claim 1 where the storage container has a permeability to water of less than 10⁻⁸ g H₂O/m²/day.

34. The packaged light source of claim 1, where each of the substrate and cover comprises a polymer layer and the storage container has a permeability to water and oxygen that is lower than that of each of the substrate polymer layer and the cover polymer layer.
